(19) United States
(12) Patent Application Publication
(10) Pub. No.: US 2026/0190840 A1
(43) Pub. Date: Jul. 2, 2026

(54) DISPLAY DEVICE

(71) Applicant: LG Display Co., Ltd., Seoul (KR)

(72) Inventors: YuCheol YANG, Goyang-si (KR); KaKyung KIM, Goyang-si (KR); Haye KIM, Goyang-si (KR); Minwoo NAM, Incheon (KR)

(73) Assignee: LG Display Co., Ltd., Seoul (KR)

(21) Appl. No.: 19/438,186

(22) Filed: Dec. 31, 2025

(30) Foreign Application Priority Data
Dec. 31, 2024 (KR) 10-2024-0202988

(51) Int. Cl. H10K 59/80; H10K 59/122; H10K 59/124; H10K 59/38

(52) U.S. Cl. CPC H10K 59/8792; H10K 59/122; H10K 59/124; H10K 59/38

(57) ABSTRACT

A display device can include a substrate having a plurality of sub-pixels, a planarization layer on the substrate, an anode on the substrate corresponding to each of the plurality of sub-pixels, a bank covering a part of the anode and having a first open area and a second open area, a first emission layer disposed on the anode exposed by the first open area, a second emission layer disposed on the anode exposed by the second open area, and a cathode disposed on the first and second emission layers and the bank. The second open area can be located on an inclined surface of the planarization layer whose thickness decreases toward the center of the sub-pixel.

### CROSS-REFERENCE TO RELATED APPLICATIONS

This application claims priority to Korean Patent Application No. 10-2024-0202988 filed on Dec. 31, 2024 in the Korean Intellectual Property Office, the entire disclosure of which is hereby expressly incorporated by reference into the present application.

### BACKGROUND

### Field

The present disclosure relates to a display device, and more particularly, to a display device capable of reducing reflectance of external light.

### Discussion of the Related Art

In general, an organic light emitting display device includes an anode, a cathode, and an organic light emitting layer disposed therebetween. As the cathode is formed using a metal material having a high reflectance, external light is reflected by the metal material to deteriorate reflection visibility and a contrast ratio. Accordingly, in order to reduce reflection due to external light, a polarizing plate for absorbing external light is disposed under the cover member. The polarizing plate is a film having a predetermined level of light transmittance and absorbs external light and reflected light thereof to prevent a decrease in contrast ratio.

Recently, as interest in flexible and slim display devices has increased, a display device to which a relatively thin coated polarizing film is applied instead of a thick polarizing plate has been proposed. However, the coated polarizing film also has a problem in that the film is relatively thick, and when the thickness is reduced, the function and display quality of the polarizing film are deteriorated.

Therefore, a Color Filter on Encapsulation (CoE) structure has been proposed instead of a polarizing plate or a coated polarizing film. The CoE structure of the related art is a structure in which a black matrix is disposed on an encapsulation layer so as to correspond to a non-emission area, and a color filter is disposed so as to correspond to the emission area. In the CoE structure, the thickness of the display device can be reduced, but the transmittance can be easily adjusted, such that external light and reflected light can be absorbed without lowering the luminous efficiency, thereby improving the display quality.

### SUMMARY OF THE DISCLOSURE

In the case of the CoE structure of the related art, since the direction of light emitted from the front surface is the same regardless of the position, there is another problem in that the luminance viewing angle is reduced and a color shift is generated. Meanwhile, in order to solve the problem of the conventional CoE structure, a pull-back structure in which the width of the color filter is formed to be wider than the width of the light-emitting area corresponding thereto has been applied. However, when the pull-back structure is applied, the width of the bank is wider than that of the black matrix so that the bank is not completely covered by the black matrix and is exposed. Accordingly, there can be a problem in that rainbow spots occur due to the exposed bank, or the reflective visibility is deteriorated due to reflection by the cathode on the exposed bank.

An object to be achieved by the present disclosure is to provide an organic light emitting display device which suppresses reflection of external light and has excellent reflection visibility.

Another problem to be solved or addressed by the present disclosure is to provide a display device having excellent viewing angle luminance.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a plurality of sub-pixels; a planarization layer on the substrate; an anode on the substrate corresponding to each of the plurality of sub-pixels; a bank covering a part of the anode and having a first open area and a second open area; a first emission layer disposed on the anode exposed by the first open area and a second emission layer disposed on the anode exposed by the second open area; and a cathode disposed on the first emission layer, the second emission layer, and the bank, wherein the second open area is located on an inclined surface of the planarization layer whose thickness decreases toward the center of the sub-pixel.

Other detailed matters of the embodiments of the present disclosure are included in the detailed description and the drawings.

According to the example embodiments of the present disclosure, it is possible to improve the luminance viewing angle through the light emitting layer formed on the inclined surface and provide a display device having excellent display quality.

According to the example embodiments of the present disclosure, by adjusting the position of the light emitting layer formed on the inclined surface and the size of the opening portion of the black matrix, it is possible to secure luminous efficiency and device life while simultaneously preventing reflection of external light and improving reflection visibility.

The effects according to the present disclosure are not limited to the contents exemplified above, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a display device according to an example embodiment of the present disclosure.

FIG. 2 is an enlarged plan view of one pixel of a display device according to an example embodiment of the present disclosure.

FIG. 3 is a cross-sectional view taken along the line I-I′ of FIG. 2 according to an example of the present disclosure.

FIG. 4 is a schematic cross-sectional view of a display device according to a comparative example.

FIG. 5 is a schematic cross-sectional view of a display device according to another embodiment of the present disclosure.

FIG. 6 is an enlarged plan view of one pixel of a display device according to still another example embodiment of the present disclosure.

FIG. 7 is a cross-sectional view taken along the line II-II′ of FIG. 6 according to an example of the present disclosure.

FIG. 8 is an enlarged plan view of one pixel of a display device according to still another example embodiment of the present disclosure.

FIG. 9 is a cross-sectional view taken along the line III-III′ of FIG. 8 according to an example of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device/apparatus according to all embodiments of the present disclosure are operatively coupled and configured.

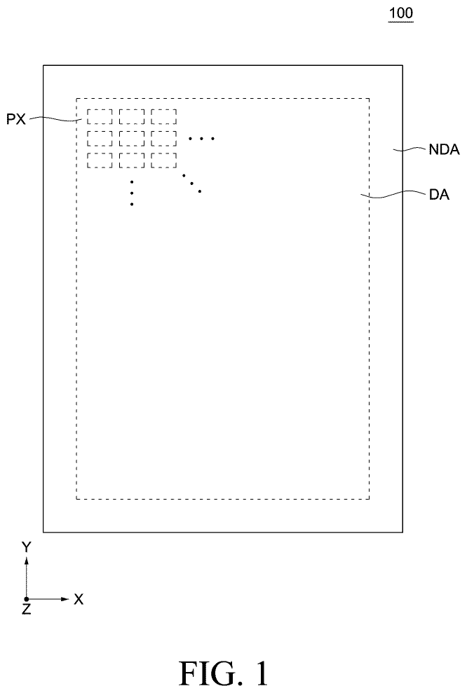

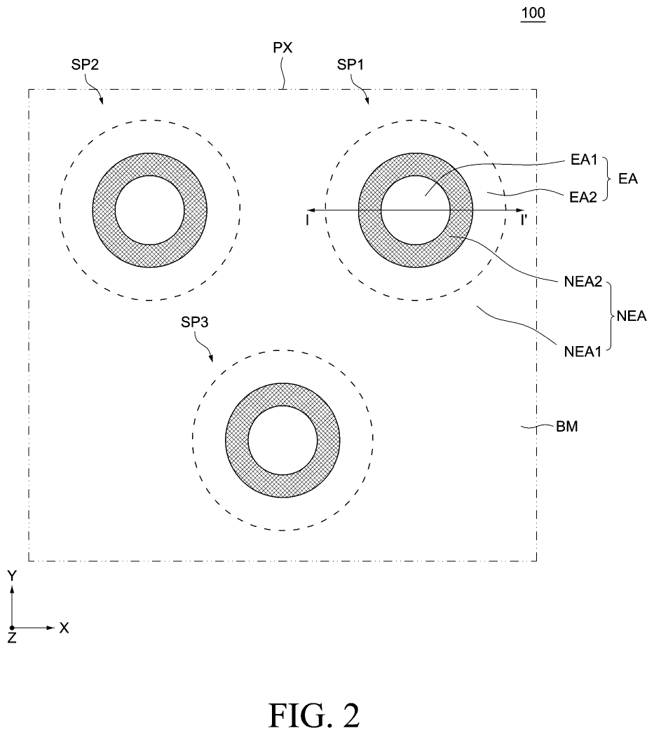

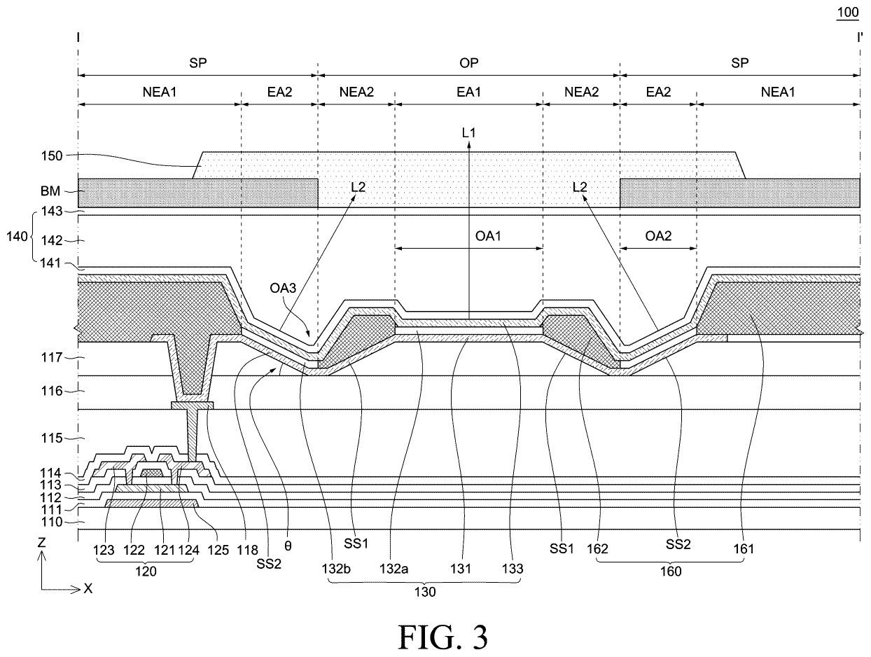

FIGS. 1 to 3 are diagrams for explaining a display device according to an example embodiment of the present disclosure. Particularly, FIG. 1 is a schematic plan view of a display device according to an example embodiment of the present disclosure. FIG. 2 is an enlarged plan view of one pixel of a display device according to an example embodiment of the present disclosure. FIG. 2 is a view schematically illustrating an emission area and a non-emission area included in one pixel. FIG. 3 is a cross-sectional view taken along the line I-I′ of FIG. 2.

Referring to FIG. 1, a display device 100 according to an example embodiment of the present disclosure includes a display area DA and a non-display area NDA. The display area DA is an area in which a plurality of pixels PX are disposed and an image is substantially displayed. In the display area DA, a pixel PX including an emission area for displaying an image and a driving circuit for driving the pixel PX can be disposed. The non-display area NDA surrounds the display area DA. The non-display area NDA is an area where an image is not substantially displayed and various wiring lines, driving ICs, printed circuit boards, and the like for driving the pixels PX and the driving circuits disposed in the display area DA are disposed. For example, various ICs such as a gate driver IC and a data driver IC can be disposed in the non-display area NDA. Meanwhile, as described above, in the non-display area NDA, a driving IC, a printed circuit board, and the like can be disposed, and a predetermined area is required to dispose the driving IC, the printed circuit board, and the like.

The plurality of pixels PX is arranged in a matrix shape, and each of the plurality of pixels PX includes a plurality of sub-pixels. The sub-pixel is an element for displaying one color and includes an emission area in which light is emitted and a non-emission area in which light is not emitted. The definition of an emission area and a non-emission area in the sub-pixel will be described with reference to FIG. 2. Each pixel PX in the display device of FIG. 1 and other figures can have the pixel configuration of FIG. 2.

Referring to FIG. 2, one pixel PX can include a first sub-pixel SP1, a second sub-pixel SP2, and a third sub-pixel SP3. For example, the first sub-pixel SP1 and the second sub-pixel SP2 can be arranged in the first direction (x-axis direction), and the third sub-pixel SP3 can be arranged along the first direction by being spaced apart from the first sub-pixel SP1 and the second sub-pixel SP2 in the second direction (y-axis direction), but is not limited thereto. The first sub-pixel SP1, the second sub-pixel SP2, and the third sub-pixel SP3 can display different colors, or if necessary, some sub-pixels can display the same color. Meanwhile, any one of the first sub-pixel SP1, the second sub-pixel SP2, and the third sub-pixel SP3 can be two or more. For example, one pixel PX can include one first sub-pixel SP1, two second sub-pixels SP2, and one third sub-pixel SP3.

Each of the first sub-pixel SP1, the second sub-pixel SP2, and the third sub-pixel SP3 can be one of a red sub-pixel, a green sub-pixel, and a blue sub-pixel. For example, the first sub-pixel SP1 can be a red sub-pixel, the second sub-pixel SP2 can be a green sub-pixel, and the third sub-pixel SP3 can be a blue sub-pixel. In this case, the second sub-pixels SP2 can be composed of two and can be arranged in a pentile structure. In the pentile structure, the second sub pixel SP2 which is green can have a smaller area than the first sub pixel SP1 which is red and the third sub pixel SP3 which is blue, in consideration of luminance and color temperature. Hereinafter, a display device according to an example embodiment of the present disclosure will be described by assuming that the first sub pixel SP1 is a red sub pixel, the second sub pixel SP2 is a green sub pixel, and the third sub pixel SP3 is a blue sub pixel. This is only an example of a color of each sub-pixel for convenience of description, but the present disclosure is not limited thereto.

In FIG. 2, it is illustrated that each of the plurality of sub pixels SP1, SP2, and SP3 has a circular shape, but it is not limited thereto and the shapes of the sub pixels SP1, SP2, and SP3 can be variously changed. For example, each of the sub-pixels SP1, SP2, and SP3 can have a polygonal shape such as an oval shape or a square shape and an octagonal shape.

Each of the plurality of sub-pixels SP1, SP2, and SP3 includes an emission area EA in which light is emitted and a non-emission area NEA in which light is not emitted. Specifically, each of the plurality of sub pixels SP1, SP2, and SP3 can include a first emission area EA1 and a second emission area EA2 which emit the same color. The first emission area EA1 is located at the center of each of the sub-pixels SP1, SP2, and SP3 and can have a circular shape in plan view. The second emission area EA2 surrounds the first emission area EA1 and is spaced apart from the first emission area EA1 to have a ring or donut shape on a plane, but is not limited thereto. As will be described below, the first emission area EA1 can be exposed by the opening portion of the black matrix BM without overlapping the black matrix BM, and the second emission area EA2 can overlap the black matrix BM and be covered by the black matrix BM.

Each of the plurality of sub-pixels SP1, SP2, and SP3 can include a first non-emission area NEA1 and a second non-emission area NEA2. The second non-emission area NEA2 can be disposed to surround the first emission area EA1, and can be disposed between the first emission area EA1 and the second emission area EA2. The first non-emission area NEA1 can be disposed to surround the second emission area EA2 and can be disposed between different sub-pixels.

Hereinafter, a structure of one of the plurality of sub pixels SP1, SP2, and SP3 will be described in more detail with reference to FIG. 3.

Referring to FIG. 3, a light emitting display device 100 according to an example embodiment of the present disclosure includes a substrate 110, a thin film transistor 120, a light emitting element 130, a bank 160, an encapsulation layer 140, a color filter 150, and a black matrix BM.

The substrate 110 is a substrate for supporting various elements constituting the display device. For example, the substrate 110 can be a plastic substrate. For example, the plastic substrate can be selected from polyimide, polyethersulfone, polyethylene terephthalate, and polycarbonate, but is not limited thereto. When a plastic substrate having flexibility is used, a support member such as a back plate can be disposed under the substrate 110.

The light shielding layer 125 can be disposed on the substrate 110. The light shielding layer 125 can be disposed below the active layer 121 of the transistor 120 and serve as a light shield. The light shielding layer 125 can be any one of magnesium (Mg), aluminum (Al), nickel (Ni), chromium (Cr), molybdenum (Mo), tungsten (W), gold (Au), titanium (Ti), neodymium (Nd), and copper (Cu), or an alloy of two or more, or can be a multilayer thereof, but is not limited thereto. For example, the light shielding layer 125 can be formed of an organic material.

A buffer layer 111 can be disposed on the light shielding layer 125. The buffer layer 111 can be configured by a single layer of silicon nitride (SiNx) or silicon oxide (SiOx), which is an inorganic material, or a multi-layer of silicon nitride (SiNx) or silicon oxide (SiOx), but is not limited thereto.

A thin film transistor TFT including an active layer 121, a gate electrode 122, a drain electrode 123, and a source electrode 124 is disposed on the buffer layer 111. The thin film transistor TFT is disposed in each of the first sub pixel SP1, the second sub pixel SP2, and the third sub pixel SP3. For convenience of description, FIG. 3 illustrates only a driving thin film transistor among various thin film transistors that can be included in the display device 100.

The active layer 121 of the transistor 120 can be disposed on the buffer layer 111. The active layer 121 can be formed of an oxide semiconductor or amorphous silicon (a-Si), polycrystalline silicon (poly-Si), or an organic semiconductor.

A gate insulating film 112 can be disposed on the active layer 121. The gate insulating film 112 can be configured by a single layer of silicon nitride (SiNx) or silicon oxide (SiOx), which is an inorganic material, or a multi-layer of silicon nitride (SiNx) or silicon oxide (SiOx), but is not limited thereto.

The gate electrode 122 can be disposed on the gate insulating film 112. The gate electrode 122 can be any one of magnesium (Mg), aluminum (Al), nickel (Ni), chromium (Cr), molybdenum (Mo), tungsten (W), gold (Au), titanium (Ti), neodymium (Nd), and copper (Cu), or an alloy of two or more, or a multilayer thereof, but is not limited thereto.

The active layer 121 can include a channel region overlapping the gate electrode 122, a source connection region located at one side of the channel region, and a drain connection region located at the other side of the channel region.

The interlayer insulating layer 113 can be disposed on the substrate 110 on which the gate electrode 122 is disposed. The interlayer insulating layer 113 can be configured by a single layer of silicon nitride (SiNx) or silicon oxide (SiOx), which is an inorganic material, or a multi-layer of silicon nitride (SiNx) or silicon oxide (SiOx), but is not limited thereto.

The source electrode 124 and the drain electrode 123 can be disposed on the interlayer insulating layer 113. The source electrode 124 and the drain electrode 123 can be any one of magnesium (Mg), aluminum (Al), nickel (Ni), chromium (Cr), molybdenum (Mo), tungsten (W), gold (Au), titanium (Ti), neodymium (Nd), and copper (Cu), or an alloy of two or more, or a multilayer thereof, but are not limited thereto. The source electrode 124 and the drain electrode 123 can be respectively connected to a source connection region and a drain connection region of the active layer 121 through a contact hole provided in the interlayer insulating layer 113.

A protection layer 114 can be disposed on the source electrode 124 and the drain electrode 123. The protective layer 114 can be configured as a single layer of silicon nitride (SiNx) or silicon oxide (SiOx) which is an inorganic material, or a multi-layer of silicon nitride (SiNx) or silicon oxide (SiOx), but is not limited thereto.

Planarization layers 115, 116, and 117 can be disposed on the protective layer 114. The planarization layers 115, 116, and 117 planarize upper portions of the transistor 120 and the protection layer 114. The planarization layers 115, 116, and 117 can include contact holes for electrically connecting the thin film transistor TFT and the anode 131 of the organic light emitting element 130. The planarization layers 115, 116, and 117 can be formed of a plurality of layers. For example, referring to FIG. 3, the planarization layers 115, 116, and 117 can include a first planarization layer 115, a second planarization layer 116, and a third planarization layer 117.

Specifically, the first planarization layer 115 can be disposed on the protective layer 114. The first planarization layer 115 can include an organic material and protect the transistor 120 and serve to planarize the upper surface of the substrate 110 on which the transistor 120 is disposed.

The connection electrode 118 can be disposed on the first planarization layer 115. The connection electrode 118 can serve to electrically connect the transistor 120 and the light emitting element 130. The connection electrode 118 can be any one of magnesium (Mg), aluminum (Al), nickel (Ni), chromium (Cr), molybdenum (Mo), tungsten (W), gold (Au), titanium (Ti), neodymium (Nd), and copper (Cu), or an alloy of two or more, or a multilayer thereof, but is not limited thereto.

The second planarization layer 116 and the third planarization layer 117 can be sequentially disposed on the connection electrode 118 and the first planarization layer 115. The second planarization layer 116 and the third planarization layer 117 can include an organic material.

The third planarization layer 117 can include a third open area OA3 partially removed (opened). The third open area OA3 can be formed by removing portions of the third planarization layer 117 corresponding to the second emission area EA2 and the second non-emission area NEA2. Since the third planarization layer 117 corresponding to the first emission area EA1 located at the center of the sub-pixel is not removed, the third open area OA3 can have a ring shape on a plane, but is not limited thereto. Further, the third open area OA3 can be formed to surround the first open area OA1 formed in the bank 160 to expose the third planarization layer 117 corresponding to the first emission area EA1 as described below.

By the third open area OA3, the upper surface and the lower surface of the third planarization layer 117 are connected, and inclined surfaces SS1 and SS2 inclined at a predetermined angle are formed. For example, in the third open area OA3, the third planarization layer 117 can include a taper having a predetermined angle. When the third open area OA3 has a ring (donut) shape on the plane, the inclined surfaces SS1 and SS2 of the third planarization layer 117 include an inner inclined surface SS1 whose thickness increases toward the center of the sub-pixel, and an outer inclined surface SS2 whose thickness decreases toward the center of the sub-pixel. The inner inclined surface SS1 is disposed adjacent to the center of the sub pixel and overlaps the second non-emission area NEA2, and the outer inclined surface SS2 is disposed adjacent to the edge of the sub pixel more than the inner inclined surface SS1 and overlaps the second emission area EA2.

Meanwhile, the inclined surfaces SS1 and SS2 of the third planarization layer 117 can have a predetermined angle. For example, when a vertical distance from the lowermost ends of the inclined surfaces SS1 and SS2 of the third planarization layer 117 to the black matrix is 8 μm to 12 μm, an angle formed between each of the inner inclined surface SS1 and the outer inclined surface SS2 of the third planarization layer 117 and the ground surface (e.g., a horizontal surface or a top flat surface of the second planarization layer 116) can be 30° to 60°. As will be described below, the second emission layer 132b is disposed on the outer inclined surface SS2 of the third planarization layer 117 so that the light can be emitted to be tilted toward the inside of the light emitting element rather than the upper direction. In this case, when the angle of the inclined surfaces SS1 and SS2 is low, the area of the second emission area EA2 can be maximized, thereby reducing the area of the first emission area EA1. Accordingly, when the area of the first emission area EA1 exposed by the opening portion of the black matrix is reduced, reflection of external light can be reduced. However, when the angle of the inclined surfaces SS1 and SS2 is less than 30°, the light emitted from the second emission area EA2 is shielded by the black matrix BM, thereby reducing the luminous efficiency and increasing the power consumption. Therefore, when an angle formed by the inclined surfaces SS1 and SS2 of the third planarization layer 117 and the ground satisfies the above range, the luminance viewing angle is improved through the second emission area EA2, and the reflectance of external light is also decreased, thereby improving power consumption and luminous efficiency.

A light emitting element 130 including an anode 131, a first emission layer 132a, a second emission layer 132b, and a cathode 133 can be disposed on the third planarization layer 117.

The anode 131 is disposed on the third planarization layer 117. The anode 131 is disposed so as to correspond to each of the plurality of sub-pixels SP1, SP2, and SP3. The anode 131 is formed of a conductive material having a high work function as a component for supplying holes to the first emission layer 132a and the second emission layer 132b. The anode 131 can be a transparent conductive layer formed of transparent conductive oxide (TCO). For example, the anode 131 can be formed of one or more selected from transparent conductive oxides such as indium-tin-oxide (ITO), indium-zinc-oxide (IZO), indium-tin-zinc oxide (ITZO), tin oxide (SnO2), zinc oxide (ZnO), indium-copper-oxide (ICO), and aluminum: zinc oxide (Al:ZnO, AZO), but is not limited thereto. When the display device 100 is driven as a top emission type, the anode 131 can further include a reflective layer to reflect light emitted from the first emission layer 132a and the second emission layer 132b toward the cathode 133.

The anode 131 can be disposed on the top surface and the inclined surfaces SS1 and SS2 of the third planarization layer 117 and disposed on the second planarization layer 116 exposed by the third open area OA3. Referring to FIG. 3, the anode 131 is disposed to overlap the first non-emission area NEA1, the second emission area EA2, the second non-emission area NEA2, and the first emission area EA1. The anode 131 is connected to the connection electrode 118 through a contact hole formed in the second planarization layer 116 and the third planarization layer 117 in the first non-emission area NEA1. The anode 131 is disposed on the outer inclined surface SS2 of the third planarization layer 117 formed by the third open area OA3 in the second emission area EA2 and disposed on the inner inclined surface SS1 of the third planarization layer 117 formed by the third open area OA3 in the first non-emission area NEA1. Further, the anode 131 is disposed on a top surface, for example, a flat surface, of the third planarization layer 117 in the first emission area EA1. FIG. 3 illustrates that the anode 131 is disposed on the inner inclined surface SS1 of the third planarization layer 117 corresponding to the second non-emission area NEA2, but may not be disposed on at least a portion of the inner inclined surface SS1 of the third planarization layer 117. For example, the anode 131 can be disposed only in a partial area of the second non-emission area NEA2 so as to connect the first emission area EA1 and the second emission area EA2.

The bank 160 can be disposed on the third planarization layer 117. The bank 160 can cover an edge of the anode 131 of the light emitting element 130 to define the emission areas EA1 and EA2. For example, the bank 160 can divide the plurality of sub pixels SP1, SP2, and SP3.

The bank 160 can be formed of an insulating material to insulate anodes 131 of adjacent sub pixels SP1, SP2, and SP3 from each other. Further, a black bank having a high light absorption rate can be configured to prevent color mixture between the sub pixels SP1, SP2, and SP3 adjacent to the bank 160. For example, the bank 160 can be formed of polyimide resin, acrylic resin, or benzocyclobutene resin, but is not limited thereto.

The bank 160 can include a first open area OA1 and a second open area OA2 that are partially removed (opened) to correspond to the emission areas EA1 and EA2 of the sub-pixel. Specifically, the first open area OA1 can be formed by removing a portion of the bank 160 corresponding to the first emission area EA1, and the second open area OA2 can be formed by removing a portion of the bank 160 corresponding to the second emission area EA2. Referring to FIG. 3, the first open area OA1 is an area in which the bank 160 is removed corresponding to the first emission area EA1 located at the center of the sub-pixel, and can have a circular shape on a plane, but is not limited thereto. Since the second open area OA2 is spaced apart from the first open area OA1 and surrounds the first open area OA1, the second open area OA2 can have a ring shape in a plan view, but is not limited thereto. In this case, the first open area OA1 is located on the flat surface of the third planarization layer 117 so as to correspond to the first emission area EA1, and the second open area OA2 is located on the outer inclined surface SS2 of the third planarization layer 117 so as to correspond to the second emission area EA2.

The bank 160 can be divided into a first bank 161 and a second bank 162 by the first open area OA1 and the second open area OA2. The second bank 162 is positioned between the first open area OA1 and the second open area OA2 and defines a first emission area EA1. The second bank 162 can have a ring shape in a plan view to surround the first open area OA1. In this case, the second bank 162 can be located on the inner inclined surface SS1 of the third planarization layer 117 so as to correspond to the second non-emission area NEA2. The first bank 161 is positioned outside the second open area OA2 and defines the second emission area EA2 together with the second bank 162. The first bank 161 corresponds to the first non-emission area NEA1 and can be positioned between sub-pixels.

The light emitting layers 132a and 132b are disposed on the anode 131. The emission layers 132a and 132b are layers in which electrons and holes are coupled to emit light. The light emitting layers 132a and 132b are disposed at portions corresponding to the emission areas EA1 and EA2. The light emitting layers 132a and 132b include a first light emitting layer 132a disposed in the first emission area EA1 and a second light emitting layer 132b disposed in the second emission area EA2. The first emission layer 132a is disposed on the anode 131 exposed by the first open area OA1 formed in the bank 160 so as to correspond to the first emission area EA1. Further, the second emission layer 132b is formed on the anode 131 exposed by the second open area OA2 formed in the bank 160 so as to correspond to the second emission area EA2. Accordingly, the first light emitting layer 132a can be positioned on the flat surface of the third planarization layer 117, and the second light emitting layer 132b can be positioned on the outer inclined surface SS2 of the third planarization layer 117. The first emission layer 132a and the second emission layer 132b can be formed of the same material and emit light of the same wavelength, but are not limited thereto.

The cathode 133 is disposed on the emission layers 132a and 132b and the bank 160. The cathode 133 can be formed of a metal material having a low work function to smoothly supply electrons to the organic emission layer 132. For example, the cathode 133 can be formed of a metal material selected from calcium (Ca), barium (Ba), aluminum (Al), silver (Ag), and an alloy including one or more of them, but is not limited thereto. Referring to FIG. 3, the cathode 133 can be formed on the anode 131 as one layer. For example, the cathode 133 can be formed in the first sub-pixel SP1, the second sub-pixel SP2, and the third sub-pixel SP3 as a single layer. When the display device 100 is driven as a top emission type organic light emitting display device, the cathode 133 can be formed to have a very thin thickness to be substantially transparent.

The encapsulation layer 140 is disposed on the light emitting element 130. The encapsulation layer 140 can cover the light emitting element 130. The encapsulation layer 140 can protect the light emitting element 130 from external moisture, oxygen, impact, and the like. The encapsulation layer 140 can have a multi-layered structure in which an inorganic layer formed of an inorganic insulating material and an organic layer formed of an organic material are stacked. For example, the encapsulation layer 140 can be configured by at least one organic layer and at least two inorganic layers, and can have a multilayer structure in which inorganic layers and organic layers are alternately stacked, but is not limited thereto. For example, the encapsulation layer 140 can have a triple-layered structure including a first inorganic layer 141, an organic layer 142, and a second inorganic layer 143. In this case, the first inorganic layer 141 and the second inorganic layer 143 can be independently formed of one or more selected from silicon nitride (SiNx), silicon oxide (SiOx), aluminum oxide (AlOx), and silicon oxynitride (SiON), but are not limited thereto. In addition, the organic layer 142 can be formed of one or more selected from epoxy resin, polyimide, polyethylene, and silicon oxycarbide (SiOC), but is not limited thereto.

A touch sensor unit can be disposed on the encapsulation layer 140 to impart a touch sensing function to the display device 100. For example, a touch electrode can be formed on the encapsulation layer 140. In this case, the touch electrode can be disposed in the non-emission area.

The color filter 150 and the black matrix BM can be disposed on the encapsulation layer 140. The color filter 150 and the black matrix BM can function as an anti-reflection layer which absorbs external light to minimize degradation of the visibility and contrast ratio of the display device 100 due to the external light.

The black matrix BM is disposed on the encapsulation layer 140. The black matrix BM is disposed along the boundary of the sub-pixels and prevents various elements from being visually recognized by the user. Further, the black matrix BM partitions each color filter 150 disposed in each sub pixel. The black matrix BM can be disposed to overlap the bank 160. Accordingly, color mixture between the sub pixels SP1, SP2, and SP3 can be minimized. Further, the black matrix BM absorbs external light to minimize deterioration in visibility and contrast ratio of the display device 100 due to the external light.

The black matrix BM includes a light shielding portion SP and an opening portion OP. The light shielding portion SP blocks light from the inside or outside of the display device 100. The opening portion OP transmits light from the inside or outside of the display device 100. The opening portion OP can correspond to the first emission area EA1 in which light is emitted from the first emission layer 132a of the light emitting element 130 and the second non-emission area NEA2 in which the first bank 161 is located. Meanwhile, the light shielding portion SP corresponds to the first non-emission area NEA1. In this case, the light shielding portion SP can correspond to the second emission area EA2 in which light is emitted from the second emission layer 132b of the light emitting element 130. In general, the opening portion OP of the black matrix BM is disposed to overlap the light-emitting area of the light-emitting element to improve light emission efficiency and luminance. However, in the display device 100 according to the example embodiment of the present disclosure, the light shielding portion SP of the black matrix BM is disposed to overlap the second emission area EA2. Even if the second emission area EA2 overlaps the light shielding portion SP of the black matrix BM on the plane of the second emission area EA2, the second emission area EA2 may not be absorbed by the light shielding portion SP because the light L2 emitted from the light emitting element 130 is emitted in a diagonal direction, for example, a direction perpendicular to the inclination of the inclined surface SS2.

The black matrix BM can be formed of an organic material. The black matrix BM includes a base resin and a black material. The base resin can be at least one selected from cardo-based resin, epoxy-based resin, acrylate-based resin, siloxane-based resin, and polyimide, but is not limited thereto. The black material can be a black pigment selected from a carbon-based pigment, a metal oxide-based pigment, and an organic pigment. For example, the carbon-based pigment can be carbon black. For example, the metal oxide-based pigment can be titanium black (TiNxOy), a Cu-Mn-Fe-based black pigment, or the like, but is not limited thereto. For example, the organic pigment can be selected from lactam black, perylene black, and aniline black, but is not limited thereto. In addition, as a black material, an RGB black pigment including a red pigment, a blue pigment, and a green pigment can be used.

The color filter 150 is disposed on the encapsulation layer 140. The color filter 150 can serve to convert a wavelength of light emitted from the light emitting element 130 into a specific wavelength. The color filter 150 is disposed in the opening portion OP of the black matrix BM. Accordingly, the color filter 150 is disposed to overlap the first emission area EA1 and the second non-emission area NEA2 of the light emitting element 130. Meanwhile, the color filter 150 can be located on the black matrix BM so as to partially overlap the light shielding portion SP of the black matrix BM due to the process margin.

The color filter 150 can overlap the anode 131, the first emission layer 132a, and the cathode 133 of the light emitting element 130 in the first emission area EA1. Accordingly, light L1 emitted from the first emission layer 132a in the first emission area EA1 can be emitted upward. Meanwhile, in the second emission area EA2 covered by the light shielding portion SP of the black matrix BM, the light emitting element 130 including the second emission layer 132b is disposed on the outer inclined surface SS2 of the third planarization layer 117. Therefore, the light L2 emitted from the second emission layer 132b is emitted in a direction perpendicular to the outer inclined surface SS2. Therefore, the light L2 emitted from the second emission layer 132b can be emitted through the color filter 150 of the opening portion OP without being shielded by the light shielding portion SP. Therefore, even though the second emission area EA2 is covered by the light shielding portion SP of the black matrix BM, the light L2 emitted from the second emission area EA2 can be emitted to the outside through the opening portion OP. Therefore, the luminance viewing angle can be improved even if the opening portion OP of the black matrix BM is not widened. In addition, since it is not necessary to expand the opening portion OP of the black matrix BM, reflection of external light by the anode 131 and the cathode 133 of the light emitting element can be reduced.

The display device according to the example embodiment of the present disclosure has a higher luminance even when the area of the opening portion of the black matrix is reduced while maintaining the area of the emission area of the light emitting element similar to that of the conventional display device, and even when viewed from the side as well as the front surface of the display device, excellent viewing angle characteristics. Specifically, in the display device according to the example embodiment of the present disclosure, the opening portion is formed in the planarization layer to form the second emission area on an inclined surface whose thickness is reduced toward the center of the sub-pixel. Therefore, it is possible to improve the luminance viewing angle as the light is tilted and emitted at a specific angle. At this time, since light is not emitted upward from the light emitting element disposed on the inclined surface, even if a black matrix is disposed above the second emission area, the amount of emitted light does not decrease. Accordingly, the black matrix can be disposed in the second emission area to reduce the opening portion of the black matrix, thereby suppressing the external light from being reflected from the inside of the display device through the opening portion of the black matrix. For this reason, it is possible to reduce the reflectance of external light and improve the reflective visibility.

In order to explain the effect of the display device according to the present disclosure, the structures of the conventional display device will be compared and described.

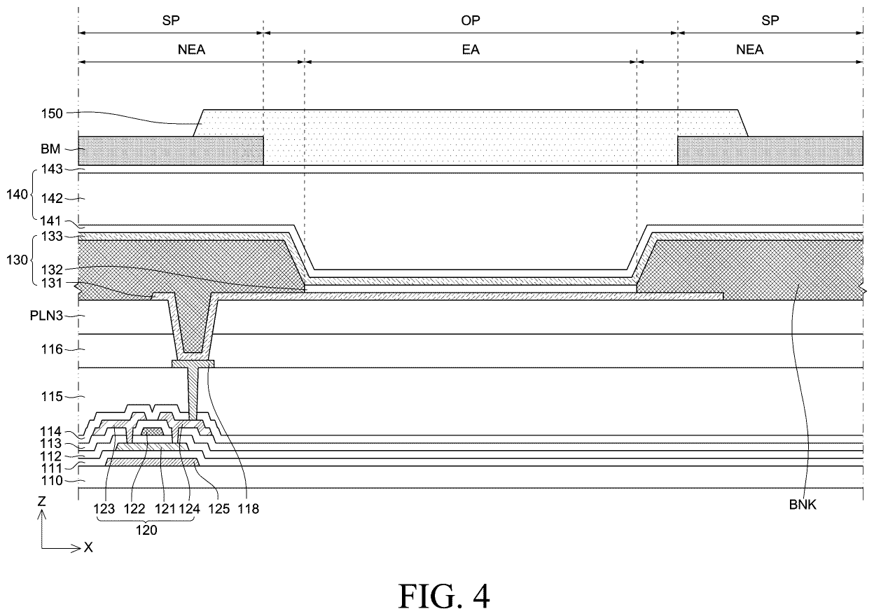

FIG. 4 is a schematic cross-sectional view of a display device according to a comparative example. As compared with FIG. 3, in the display device according to the comparative example, since the open area is not formed in the third planarization layer PLN3, one emission area EA is formed on the flat surface of the third planarization layer PLN3. Accordingly, light emitted from the light emitting layer 132 of the light emitting element 130 is emitted through the opening portion OP of the black matrix BM in the vertical direction. In this case, in the display device illustrated in FIG. 4, in order to improve the luminance viewing angle, the opening portion OP of the black matrix BM is larger than the emission area EA, and the side portion of the black matrix BM has a pull-back structure disposed at the outside than the side portion of the bank BNK. In this case, some light emitted from the light emitting element 130 can be emitted to the side surface, thereby improving the luminance viewing angle and the color viewing angle. However, in order to implement a pull-back structure, when the size of the opening portion OP of the black matrix BM is expanded, the exposed areas of the anode 131 and the cathode 133 of the light emitting element are increased. As a result, there can be a problem in that the reflectance of external light increases. In addition, in order to implement a pull-back structure while maintaining the size of the opening portion OP of the black matrix BM, when the open area of the bank BNK is reduced, the area of the light-emitting area decreases, which can cause a problem in that the luminous efficiency and the lifespan of the device decrease.

However, in the display device according to the embodiment of the present disclosure illustrated in FIG. 3, an inclined surface is formed on the third planarization layer 117 to form a second emission area on the inclined surface, such that light emitted from the light emitting element disposed on the inclined surface is tilted toward the inside of the light emitting element rather than upward direction and emitted, so that the luminance viewing angle can be improved without expanding the opening portion of the black matrix. Further, compared with the display device illustrated in FIG. 4, the display device illustrated in FIG. 3 has a smaller opening portion OP area of the black matrix BM, thereby reducing the reflectance of external light and reducing the amount of light incident from the outside into the display device, thereby improving the reflective visibility. In addition, as compared with the display device illustrated in FIG. 4, the display device illustrated in FIG. 3 has a small size of the first light-emitting area exposed by the opening portion OP of the black matrix BM. Therefore, the sum of the areas of the first light-emitting area and the second light-emitting area can be designed to be similar to the areas of the light-emitting area EA of the display device illustrated in FIG. 4, so that the luminous efficiency and the device lifespan may not be degraded. Accordingly, in the display device according to the example embodiment of the present disclosure, it is possible to achieve both an emission efficiency and a device life while minimizing the expansion of the viewing angle and reflection of external light.

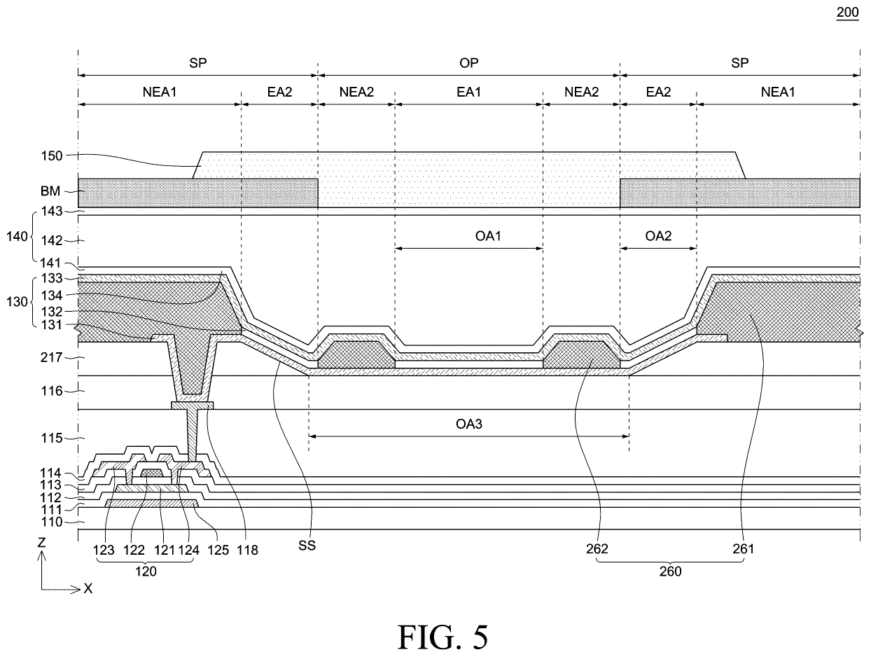

FIG. 5 is a schematic cross-sectional view of a display device according to another embodiment of the present disclosure. A display device 200 illustrated in FIG. 5 has the substantially same configurations as the display device 100 illustrated in FIGS. 1 to 3, except that structures of a third planarization layer 217 and a bank 260 are different, so that a redundant description will be omitted or may be briefly provided.

Referring to FIG. 5, the third planarization layer 217 can include not only the second emission area EA2 and the second non-emission area NEA2, but also a third open area OA3 in which a portion corresponding to the first emission area EA1 is removed. Since the third planarization layer 217 corresponding to the first emission area EA1 and the second non-emission area NEA2 located at the center of the sub-pixel is not removed, the third open area OA3 can have a circular shape on a plane. In this case, the third open area OA3 can have a larger size than the opening portion OP of the black matrix BM.

The inclined surface SS inclined at a predetermined angle is formed by the third open area OA3. When the third open area OA3 has a circular shape in plan view, the inclined surface SS of the third planarization layer 217 includes only an inclined surface whose thickness decreases toward the center of the sub-pixel. The inclined surface SS of the third planarization layer 217 is formed to overlap the second emission area EA2 and overlaps the light shielding portion SP of the black matrix BM.

The bank 260 can include a first open area OA1 and a second open area OA2 that are partially removed (opened) to correspond to the emission areas EA1 and EA2 of the sub-pixel. Specifically, the first open area OA1 can be formed by removing a portion of the bank 260 corresponding to the first emission area EA1, and the second open area OA2 can be formed by removing a portion of the bank 260 corresponding to the second emission area EA2. Referring to FIG. 5, the first open area OA1 is an area in which the bank 260 is removed corresponding to the first emission area EA1 located at the center of the sub-pixel, and can have a circular shape in plan view, but is not limited thereto. Since the second open area OA2 is spaced apart from the first open area OA1 and surrounds the first open area OA1, the second open area OA2 can have a ring shape in a plan view, but is not limited thereto. In this case, because the first open area OA1 corresponds to the first emission area EA1 and overlaps the third open area OA3 of the third planarization layer 217, the first open area OA1 is located on the flat surface of the exposed second planarization layer 116, and the second open area OA2 is located on the inclined surface of the third planarization layer 217 to correspond to the second emission area EA2.

Accordingly, the bank 260 can be divided into a first bank 261 and a second bank 262 by the first open area OA1 and the second open area OA2. In this case, the second bank 262 has a ring shape in a plan view to surround the first open area OA1 and can be located on the flat surface of the second planarization layer 116 exposed by the third open area OA3 of the third planarization layer 217 to correspond to the second non-light-emitting area NEA2.

The display device 200 according to FIG. 5 forms an open area in the planarization layer to form a second emission area on an inclined surface whose thickness decreases toward the center of the sub-pixel. Therefore, it is possible to improve the luminance viewing angle as the light is tilted and emitted at a specific angle. Further, the light emitting element disposed on the inclined surface does not emit light upward. Therefore, even though the black matrix is disposed above the second emission area, the amount of emitted light does not decrease so that the black matrix can be disposed above the second emission area. For example, it is possible to improve the viewing angle and reduce external light reflection without the need to expand the opening portion of the black matrix. Furthermore, in order to implement the conventional pull-back structure, there is no need to reduce the area of the light-emitting area, and thus luminous efficiency and device life can also be improved.

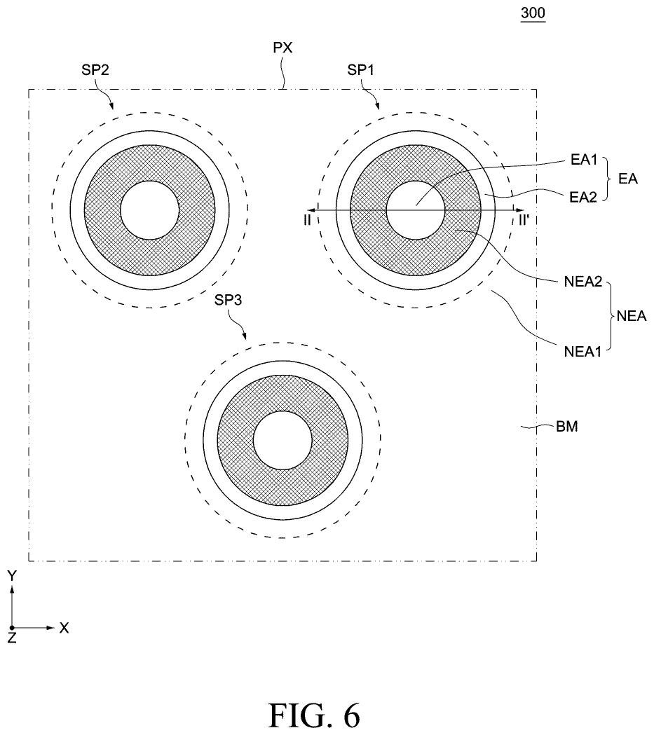

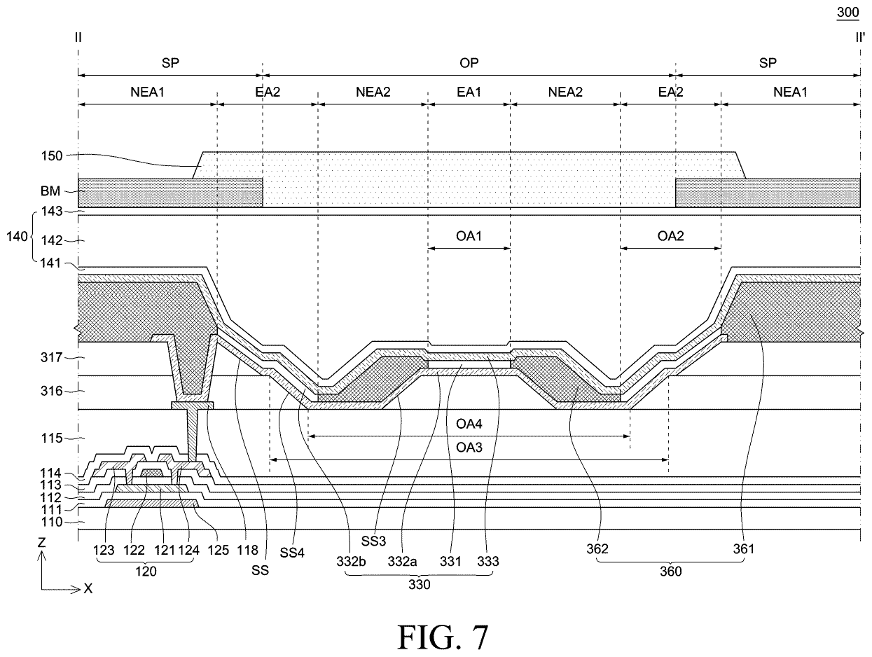

FIG. 6 is an enlarged plan view of one pixel of a display device according to still another example embodiment of the present disclosure. FIG. 7 is a cross-sectional view taken along the line II-II′ of FIG. 6. A display device 300 illustrated in FIGS. 6 and 7 has the substantially same configurations as the display device 100 illustrated in FIGS. 1 to 3 except that structures of a second planarization layer 316, a third planarization layer 317, a light emitting element 330, and a bank 360 are different, so that a redundant description will be omitted or may be briefly provided.

Referring to FIG. 7, the third planarization layer 317 can include not only the second emission area EA2 and the second non-emission area NEA2, but also a third open area OA3 from which a portion corresponding to the first emission area EA1 is removed. Since the third planarization layer 317 is continuously removed from the first emission area EA1 to the second emission area EA2 located at the center of the sub-pixel, the third open area OA3 can have a circular shape in a plan view. In this case, the third open area OA3 can have a larger size than the opening OP of the black matrix BM.

The second planarization layer 316 can include a fourth open area OA4 partially removed (opened). The fourth open area OA4 can be formed by removing a portion of the second emission area EA2 and a portion corresponding to the second non-emission area NEA2. Since the second planarization layer 316 corresponding to the first emission area EA1 located at the center of the sub-pixel is not removed in the fourth open area OA4, the fourth open area OA4 can have a ring shape in a plan view, but is not limited thereto. The fourth open area OA4 can overlap the third open area OA3 of the third planarization layer 317.

An inclined surface inclined at a predetermined angle is formed by the third open area OA3 and the fourth open area OA4, respectively. First, when the third open area OA3 has a circular shape in plan view, the inclined surface SS of the third planarization layer 317 includes only an inclined surface whose thickness decreases toward the center of the sub-pixel. The inclined surface SS of the third planarization layer 317 is formed to overlap a portion of the second emission area EA2. Further, at least a part of the inclined surface SS of the third planarization layer 317 can overlap the light shielding portion SP of the black matrix BM.

By the fourth open area OA4, inclined surfaces SS3 and SS4 are formed on the second planarization layer 316. Since the fourth open area OA4 has a ring (donut) shape on a plane, the inclined surfaces SS3 and SS4 of the second planarization layer 316 include an inner inclined surface SS3 which increases in thickness toward the center of the sub-pixel, and an outer inclined surface SS4 which decreases in thickness toward the center of the sub-pixel. The inner inclined surface SS3 is disposed adjacent to the center of the sub pixel and overlaps the second non-emission area NEA2, and the outer inclined surface SS4 is disposed adjacent to the edge of the sub pixel than the inner inclined surface SS3 and is formed to overlap the second emission area EA2. In this case, the outer inclined surface SS4 can overlap the opening portion OP of the black matrix BM.

Meanwhile, the inclined surface SS of the third planarization layer 317 and the outer inclined surface SS4 of the second planarization layer 316 can be connected to each other to form a continuous inclined surface, but are not limited thereto. For example, the upper surface of the second planarization layer 316 can be exposed between the inclined surface SS of the third planarization layer 317 and the outer inclined surface SS4 of the second planarization layer 316.

A light emitting element 330 including an anode 331, a first light emitting layer 332a, a second light emitting layer 332b, and a cathode 333 can be disposed on the second planarization layer 316 and the third planarization layer 317.

The anode 331 is disposed on the second planarization layer 316 and the third planarization layer 317. The anode 331 can be disposed on the top surface of the second planarization layer 316 exposed by the third open area OA3, the inclined surfaces SS3 and SS4 of the second planarization layer 316 exposed by the fourth open area OA4, and the top surface of the first planarization layer 115. Further, the anode 331 can be disposed on the inclined surface SS of the third planarization layer 317 exposed by the third open area OA3. Referring to FIG. 7, the anode 331 is disposed to overlap the first non-emission area NEA1, the second emission area EA2, the second non-emission area NEA2, and the first emission area EA1. The anode 331 is connected to the connection electrode 118 through a contact hole formed in the second planarization layer 316 and the third planarization layer 317 in the first non-emission area NEA1. The anode 331 is disposed on the inclined surface SS of the third planarization layer 317 formed by the third open area OA3 in the second emission area EA2 and the outer inclined surface SS4 of the second planarization layer 316 formed by the fourth open area OA4, and disposed on the inner inclined surface SS3 of the second planarization layer 316 formed by the fourth open area OA4 in the second non-emission area NEA2 and the flat surface of the first planarization layer 115. Further, the anode 331 is disposed on the top surface, for example, the flat surface of the second planarization layer 316 in the first emission area EA1.

The bank 360 can include a first open area OA1 and a second open area OA2 that are partially removed (opened) to correspond to the emission area of the sub-pixel. Specifically, the first open area OA1 can be formed by removing a portion of the bank 360 corresponding to the first emission area EA1, and the second open area OA2 can be formed by removing a portion of the bank 360 corresponding to the second emission area EA2. Accordingly, the bank 360 includes a first bank 361 and a second bank 362 by the first open area OA1 and the second open area OA2. In this case, the second bank 362 has a ring shape in a plan view to surround the first open area OA1 and can be located on the third open area OA3 of the third planarization layer 317 and the inner inclined surface SS3 of the second planarization layer 316 to correspond to the second non-light-emitting area NEA2.

In the display device 300 illustrated in FIGS. 6 and 7, the first emission area EA1 is positioned so as to correspond to the opening portion OP of the black matrix BM, and the second emission area EA2 is positioned at a boundary between the opening portion OP and the light shielding portion SP. For example, a part of the second emission area EA2 overlaps the opening portion OP, and the rest overlaps the light shielding portion SP. For example, a part of the second emission area EA2 corresponding to the inclined surface SS of the third planarization layer 317 can overlap the light shielding portion SP, and the rest of the second emission area EA2 corresponding to the outer inclined surface SS4 of the second planarization layer 316 can overlap the opening portion OP.

In comparison with the display device 100 illustrated in FIGS. 1 to 3, the display device 300 illustrated in FIGS. 6 and 7 can be disposed so that a part of the second emission area EA2 is exposed from the outside through the opening portion OP. Accordingly, the size of the first emission area EA1 located at the center of the sub-pixel can be reduced, and the size of the second emission area EA2 located on the inclined surface of the planarization layer can be increased. Accordingly, light is tilted and emitted at a specific angle to improve luminance viewing angle. In particular, from the viewpoint of maintaining the same planar area of the first emission area EA1 and the second emission area EA2 of the display device illustrated in FIGS. 6 and 7 and the display device illustrated in FIGS. 1 to 3, it is possible to increase the area of the second non-emission area NEA2 instead of reducing the size of the first emission area EA1 in the display device 300 illustrated in FIGS. 6 and 7. As the area of the second non-emission area NEA2 in which the second bank 362 is located increases, the size of the opening portion OP of the black matrix BM can also increase. Accordingly, the display device illustrated in FIGS. 6 and 7 can maintain the reflectance of external light even when the size of the opening portion OP of the black matrix BM increases compared to the display device illustrated in FIGS. 1 to 3.

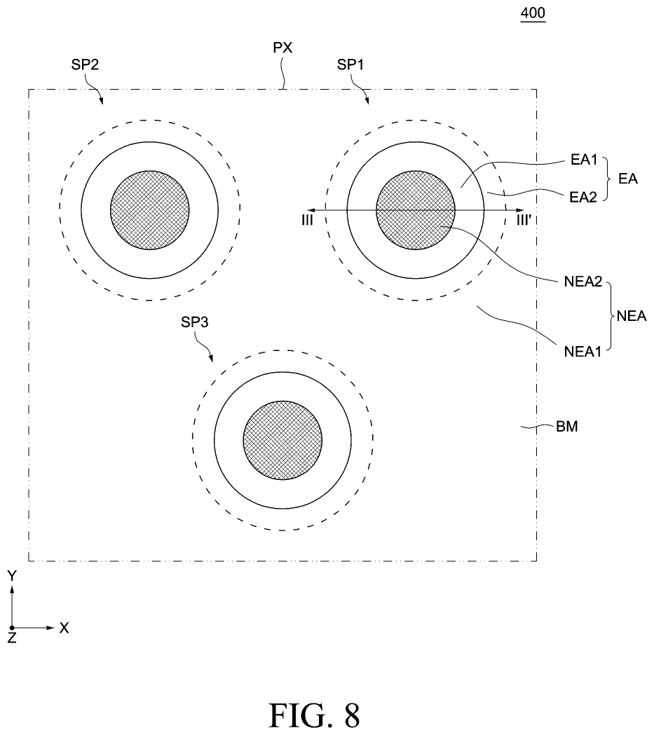

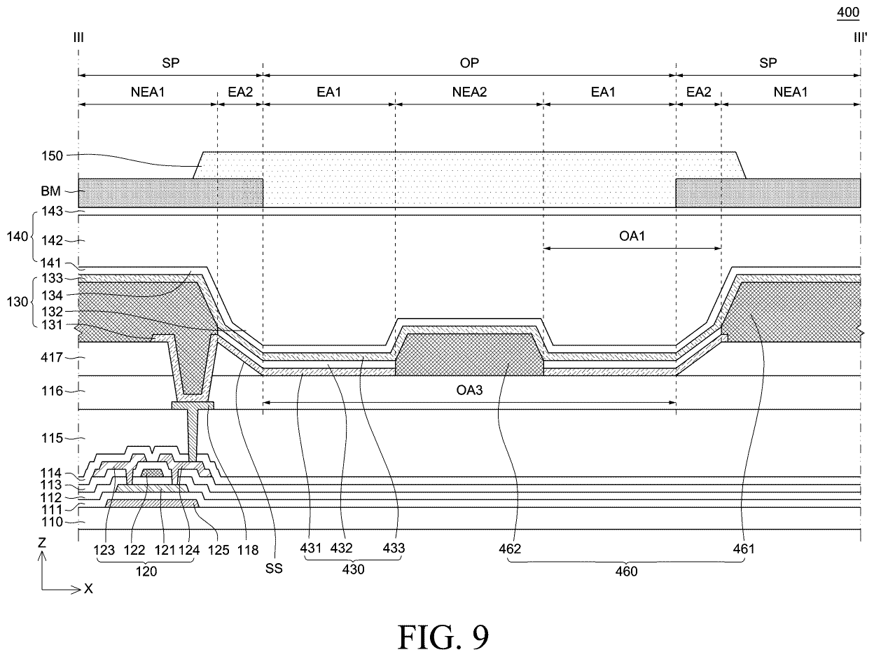

FIG. 8 is an enlarged plan view of one pixel of a display device according to still another example embodiment of the present disclosure. FIG. 9 is a cross-sectional view taken along the line III-III′ of FIG. 8. A display device 400 illustrated in FIGS. 8 and 9 has the substantially same configurations as the display device 100 illustrated in FIGS. 1 to 3 except that structures of a third planarization layer 417, a light emitting element 430, and a bank 460 and the first emission area EA1 and the second emission area EA2 are different from each other. Therefore, a redundant description will be omitted or may be briefly provided.

First, referring to FIG. 9, each of the plurality of sub-pixels SP1, SP2, and SP3 can include a first non-emission area NEA1 and a second non-emission area NEA2. In this case, the second non-emission area NEA2 is located at the center of the sub-pixel. The first emission area EA1 is disposed to surround the first non-emission area NEA1, and the second emission area EA2 is disposed to surround the first emission area EA1. In this case, the first emission area EA1 and the second emission area EA2 are connected to each other to have a ring shape in a plan view that surrounds the second non-emission area NEA2, but are not limited thereto.

The third planarization layer 417 can include a third open area OA3 partially removed (opened). The third planarization layer 417 can include not only the second emission area EA2 and the second non-emission area NEA2, but also a third open area OA3 in which a portion corresponding to the first emission area EA1 is removed. Since the third planarization layer 417 is continuously removed from the first emission area EA1 to the second emission area EA2 located at the center of the sub-pixel, the third open area OA3 can have a circular shape in a plan view. In this case, the third open area OA3 can have a larger size than the opening portion OP of the black matrix BM.

The inclined surface SS inclined at a predetermined angle is formed by the third open area OA3. When the third open area OA3 has a circular shape in plan view, the inclined surface SS of the third planarization layer 417 includes only the inclined surface SS whose thickness decreases toward the center of the sub-pixel. The inclined surface SS of the third planarization layer 417 is formed to overlap the second emission area EA2 and overlaps the light shielding portion SP of the black matrix BM.

The bank 460 can include a first open area OA1 that is partially removed (opened) to correspond to the emission area of the sub-pixel. Specifically, referring to FIG. 9, since the first emission area EA1 and the second emission area EA2 are connected to each other, the first open area OA1 of the bank 460 can be formed to simultaneously correspond to the first emission area EA1 and the second emission area EA2, and thus it can be deemed as including both the first open area and the second open area that are in contact with each other. Referring to FIG. 9, the first open area OA3 can have a ring shape in a plan view, but is not limited thereto.

The bank 460 includes a first bank 461 corresponding to the first non-emission area NEA1 and a second bank 462 corresponding to the second non-emission area NEA2. In this case, the second bank 462 can be located at the center of the sub-pixel, have a circular shape in a plane, and can be located on the flat surface of the second planarization layer 116 exposed by the third open area OA3 of the third planarization layer 417.

The display device 400 illustrated in FIGS. 8 and 9 is located at the center of the sub pixel of the second non-emission area NEA2, and the first emission area EA1 and the second emission area EA2 are disposed to surround the second non-emission area NEA2. In this case, the first emission area EA1 overlaps the opening portion OP of the black matrix BM, and the second emission area EA2 corresponding to the inclined surface of the third planarization layer 417 overlaps the light shielding portion SP of the black matrix BM.

Compared with the display device illustrated in FIGS. 5 to 6, the display device 400 illustrated in FIGS. 8 and 9 maintains the same planar area of the first emission area EA1 and the second emission area EA2 so that the size of the opening portion OP of the black matrix BM can be increased instead of being located at the center of the sub pixel of the second non-emission area NEA2. Accordingly, the display device illustrated in FIGS. 8 and 9 can maintain the reflectance of external light even when the size of the opening portion OP of the black matrix BM increases compared to the display device illustrated in FIGS. 5 and 6.

The example embodiments of the present disclosure can also be described as follows:

According to an aspect of the present disclosure, a display device includes a substrate including a plurality of sub-pixels; a planarization layer on the substrate; an anode on the substrate corresponding to each of the plurality of sub-pixels; a bank covering a part of the anode and having a first open area and a second open area; a first emission layer disposed on the anode exposed by the first open area and a second emission layer disposed on the anode exposed by the second open area; and a cathode disposed on the first emission layer, the second emission layer, and the bank, wherein the second open area is located on an inclined surface of the planarization layer whose thickness decreases toward the center of the sub-pixel.

The inclined surface can have an angle of 30° to 60° formed with the ground.

The first open area can be located on the flat surface of the planarization layer, and the second open area can be located on the inclined surface of the planarization layer inclined toward the center of the anode.

The second open area is disposed outside the first open area and can surround the first open area.

The second open area can be spaced apart from the first open area.

The bank can include a first bank configured to cover an edge of the anode and a second bank disposed on the anode to overlap the anode, and the second bank can be spaced apart from the first bank.

The second bank can surround the first open area to define the first open area, and the second open area can be located between the second bank and the first bank.

The second open area can be in contact with the first open area.

The bank can include a first bank covering an edge of the anode and a second bank disposed on the anode to overlap the anode, the first open area and the second open area can be located between the first bank and the second bank.

The planarization layer can include a first planarization layer, a second planarization layer, and a third planarization layer sequentially disposed on the substrate, the third planarization layer can include a third open area having a circular shape exposing the second planarization layer, and the second bank can be disposed within the third open area and can be in contact with the second planarization layer.

The planarization layer can include a first planarization layer, a second planarization layer, and a third planarization layer sequentially disposed on the substrate, the third planarization layer can include a third open area having a ring-shape to expose the second planarization layer, the third planarization layer can include an inner inclined surface adjacent to the anode center formed by the third open area and an outer inclined surface adjacent to the anode outer side, and the second bank can be disposed on the inner inclined surface of the third planarization layer.

The planarization layer can include a first planarization layer, a second planarization layer, and a third planarization layer sequentially disposed on the substrate, the third planarization layer can include a third open area having a circular shape to expose the second planarization layer, the second planarization layer can include a fourth open area having a ring shape to expose the first planarization layer, and the second emission layer can be disposed on an inclined surface of the third planarization layer formed by the third open area and an inclined surface of the second planarization layer formed by the fourth open area.

The second planarization layer can include an inner inclined surface adjacent to the anode center formed by the fourth open area and an outer inclined surface adjacent to the anode outer side, and the second bank can be disposed on the inner inclined surface of the second planarization layer.

The display device can further comprise an encapsulation layer disposed on the cathode; a plurality of color filters disposed on the encapsulation layer corresponding to each of the plurality of sub-pixels; and a black matrix partitioning each of the plurality of color filters, the black matrix can include an opening portion through which light emitted from the first emission layer and the second emission layer emits light and a light shielding portion surrounding the open portion.

The opening portion can overlap the first open area, and the light shielding portion can overlap the second open area.

The light shielding portion can overlap a portion of the second open area.

In the display device, each of the plurality of sub-pixels can be composed of multiple emission areas and at least one non-emission area disposed between the multiple emission areas, and the multiple emission areas and the at least one non-emission area are arranged to be in a shape of concentric circles.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present invention. The protective scope of the present disclosure should be construed based on the following claims, and all the technical concepts in the equivalent scope thereof should be construed as falling within the scope of the present disclosure.

What is claimed is:

1. A display device comprising:
a substrate including a plurality of sub-pixels;
a planarization layer on the substrate;
an anode on the substrate corresponding to a sub-pixel among the plurality of sub-pixels;
a bank covering a part of the anode and having a first open area and a second open area;
a first emission layer disposed on the anode exposed by the first open area of the bank, and a second emission layer disposed on the anode exposed by the second open area of the bank; and
a cathode disposed on the first emission layer, the second emission layer, and the bank,
wherein the second open area of the bank is located on an inclined surface of the planarization layer whose thickness decreases toward a center of the sub-pixel.

2. The display device according to claim 1, wherein the inclined surface of the planarization layer has an angle of 30° to 60°.

3. The display device according to claim 1, wherein the first open area of the bank is located on a flat surface of the planarization layer, and the second open area of the bank is located on inclined surface of the planarization layer inclined toward a center of the anode.

4. The display device according to claim 3, wherein the second open area of the bank is disposed outside the first open area of the bank and encloses the first open area of the bank.

5. The display device of claim 4, wherein the second open area of the bank is spaced apart from the first open area of the bank.

6. The display device according to claim 5, wherein the bank includes a first bank covering an edge of the anode and a second bank disposed on the anode to overlap the anode, and
the second bank is spaced apart from the first bank.

7. The display device of claim 6, wherein the second bank encloses the first open area to define the first open area of the bank, and
the second open area is located between the second bank and the first bank.

8. The display device according to claim 1, wherein the second open area of the bank is in contact with the first open area of the bank.

9. The display device according to claim 8, wherein the bank includes a first bank covering an edge of the anode and a second bank disposed on the anode to overlap the anode, and
the first open area and the second open area are located between the first bank and the second bank.

10. The display device according to claim 7, wherein the planarization layer includes a first planarization layer, a second planarization layer, and a third planarization layer sequentially disposed on the substrate,
the third planarization layer includes a third open area to expose the second planarization layer, and
the second bank is disposed in the third open area of the third planarization layer and is in contact with the second planarization layer.

11. The display device according to claim 10, wherein the third open area of the third planarization layer has a circular shape.

12. The display device according to claim 7, wherein the planarization layer includes a first planarization layer, a second planarization layer, and a third planarization layer sequentially disposed on the substrate,
the third planarization layer includes a third open area to expose the second planarization layer,
the third planarization layer includes an inner inclined surface adjacent to a center of the anode formed by the third open area of the third planarization layer and an outer inclined surface adjacent to an outside of the anode, and
the second bank is disposed on the inner inclined surface of the third planarization layer.

13. The display device according to claim 12, wherein the third open area of the third planarization layer has a ring-shape.

14. The display device according to claim 7, wherein the planarization layer includes a first planarization layer, a second planarization layer, and a third planarization layer sequentially disposed on the substrate,
the third planarization layer includes a third open area to expose the second planarization layer,
the second planarization layer includes a fourth open area to expose the first planarization layer, and
the second emission layer is disposed on an inclined surface of the third planarization layer formed by the third open area of the third planarization layer and an inclined surface of the second planarization layer formed by the fourth open area.

15. The display device according to claim 14, wherein the third open area of the third planarization layer has a circular shape, and the fourth open area of the second planarization layer has a ring shape.

16. The display device according to claim 14, wherein the second planarization layer includes an inner inclined surface adjacent to a center of the anode formed by the fourth open area of the second planarization layer and an outer inclined surface adjacent to an outer side of the anode, and
the second bank is disposed on the inner inclined surface of the second planarization layer.

17. The display device according to claim 1, further comprising:
an encapsulation layer disposed on the cathode;
a plurality of color filters disposed on the encapsulation layer corresponding to the plurality of sub-pixels; and
a black matrix partitioning the plurality of color filters,
wherein the black matrix includes an opening portion through which light emitted from the first emission layer and the second emission layer is emitted, and a light shielding portion surrounding the opening portion of the black matrix.

18. The display device according to claim 17, wherein the opening portion of the black matrix overlaps the first open area of the bank. and the light shielding portion of the black matrix overlaps the second open area of the bank.

19. The display device according to claim 17, wherein the light shielding portion of the black matrix overlaps a portion of the second open area of the bank.

20. The display device according to claim 1, wherein each of the plurality of sub-pixels is composed of multiple emission areas and at least one non-emission area disposed between the multiple emission areas, and
the multiple emission areas and the at least one non-emission area are arranged to be in a shape of concentric circles.
